(19) United States
(12) Patent Application Publication
(10) Pub. No.: US 2026/0066035 A1
(43) Pub. Date: Mar. 5, 2026

(54) MEMORY PACKAGES WITH ADDITIONAL REDUNDANT STORAGE

(71) Applicant: Micron Technology, Inc., Boise, ID (US)

(72) Inventors: Randall J. Rooney, Boise, ID (US); Matthew A. Prather, Boise, ID (US); Navid Lashkarian, Pleasanton, CA (US); Anthony D. Veches, Boise, ID (US); Sujeet Ayyapureddi, Boise, ID (US)

(73) Assignee: Micron Technology, Inc., Boise, ID (US)

(21) Appl. No.: 19/292,400

(22) Filed: Aug. 6, 2025

Related U.S. Application Data
(60) Provisional application No. 63/689,068, filed on Aug. 30, 2024.

(51) Int. Cl. G11C 29/00; G11C 11/408

(52) U.S. Cl. CPC G11C 29/76; G11C 11/4087; G11C 29/702

(57) ABSTRACT

A memory package may include multiple memory devices and an additional die in some examples. The memory package may be included on a memory module. The memory module may include multiple memory packages. The additional die may include components that reduce or eliminate a number of components on the memory module. In some embodiments, the additional die includes redundant storage for storing data associated with defective memory cells in the memory arrays on the multiple memory devices. The redundant storage can supplement redundant memory on the multiple memory devices or replace the redundant memory on the multiple memory devices.

### CROSS-REFERENCE TO RELATED APPLICATION(S)

This application claims the benefit of U.S. Provisional Patent Application No. 63/689,068, filed on Aug. 30, 2024, and titled “Memory Packages with Buffer Die and Modules with Same.” The aforementioned application is incorporated herein by reference, in its entirety, for any purpose.

### BACKGROUND

Semiconductor memory devices are widely used in various electronic devices such as computers, wireless communication devices, cameras, digital displays, and the like. Some memory devices, such as a dynamic random-access memory (DRAM), include memory cells that may be arranged in addressable groups (e.g., rows or columns) within a memory array. Information may be stored in the memory cells, typically as single bit of information as either a logical high (e.g., a “1”) or a logical low (e.g., a “0”). When a memory controller receives a request to access a row or a column of memory cells, such as when performing a read or write operation, the memory controller may activate access to the row and/or column of memory cells. However, due to manufacturing errors and/or failures, certain memory cells may be defective. For example, a memory cell may not be able to store information and may need to be repaired.

### BRIEF DESCRIPTION OF THE DRAWINGS

Non-limiting and non-exhaustive examples are described with reference to the following Figures. The elements of the drawings are not necessarily to scale relative to each other.

FIG. 1 illustrates a block diagram of at least a portion of an example system according to an embodiment of the disclosure;

FIG. 2 illustrates an example of a multi-die device according to an embodiment of the disclosure;

FIG. 3 illustrates another example of a multi-die device according to an embodiment of the disclosure;

FIG. 4 illustrates a block diagram of an example semiconductor device according to an embodiment of the disclosure;

FIG. 5 illustrates a block diagram of a portion of an example memory package 500 according to an embodiment of the disclosure;

FIG. 6 illustrates a block diagram of an example additional die according to an embodiment of the disclosure; and

FIG. 7 illustrates a flowchart of an example method according to an embodiment of the disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized, and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Memory cells of memory devices, such as DRAMs, static RAMs (SRAMs), flash memories, or the like, can experience defects leading to errors and/or failures. For example, rows containing defective memory cells may generally be referred to as defective rows. The defective rows may be incapable of storing information and/or may become otherwise inaccessible to the memory device. After a memory device is packaged, the memory device can be tested to identify defective memory cells. The addresses for memory cells that are mapped or assigned to defective memory cells can be remapped to non-defective memory cells (i.e., functional) so that the memory device can still be effective.

For example, a memory array may generally include a number of additional rows of memory, which may generally be referred to as redundant memory. During a repair operation, a row address associated with a defective row may be redirected or remapped so that the row address is associated with one of the redundant rows instead. The remapped addresses may be stored in non-volatile storage in the memory device. For example, the memory device may include one or more fuse arrays that can include fuses (and/or anti-fuses) which may have state that can be permanently changed (e.g., when the fuse/anti-fuse is “blown”). The state of the fuses/anti-fuses in the fuse bank may, in part, determine which addresses are associated with which rows of memory.

The number of memory cells in the redundant memory is fixed and typically cannot be changed after the memory device is designed or packaged. Additionally, the information stored in the fuses or anti fuses is fixed and cannot be changed once the fuses or anti-fuses are blown. Due to these limitations, some memory devices increase the amount of redundant memory in a memory array, which can result in unused memory cells in redundant memory. In some instances, the additional redundant memory can increase the size of the memory array.

Embodiments of a memory package disclosed herein can include one or more memory devices and at least one additional die. The one or more memory devices may be stacked on each other to produce a stacked memory package. One or more memory packages may be included on a memory module. The additional die can include components that facilitate communication with a controller, a host system, and/or between memory packages. The additional die may include components for providing redundant storage that can be used to remap the addresses for defective memory cells. The redundant storage on the additional die can supplement the redundant memory in the memory array, which may increase yields for memory packages. The redundant storage on the additional die may replace at least a portion of the redundant memory in the memory array, which may reduce the size of the redundant memory and/or the memory array. In some embodiments, the redundant storage on the additional die may replace the redundant memory in the memory array, which can enable more of the memory cells in the memory array to be used for data storage. In some embodiments, the additional die may be a buffer die, but other embodiments are not limited to this implementation. The additional die may be any die or additional die in the memory package. For example, an additional memory device may be included in a memory package, where the memory array and/or the redundant memory on the additional memory device is used for additional redundant storage.

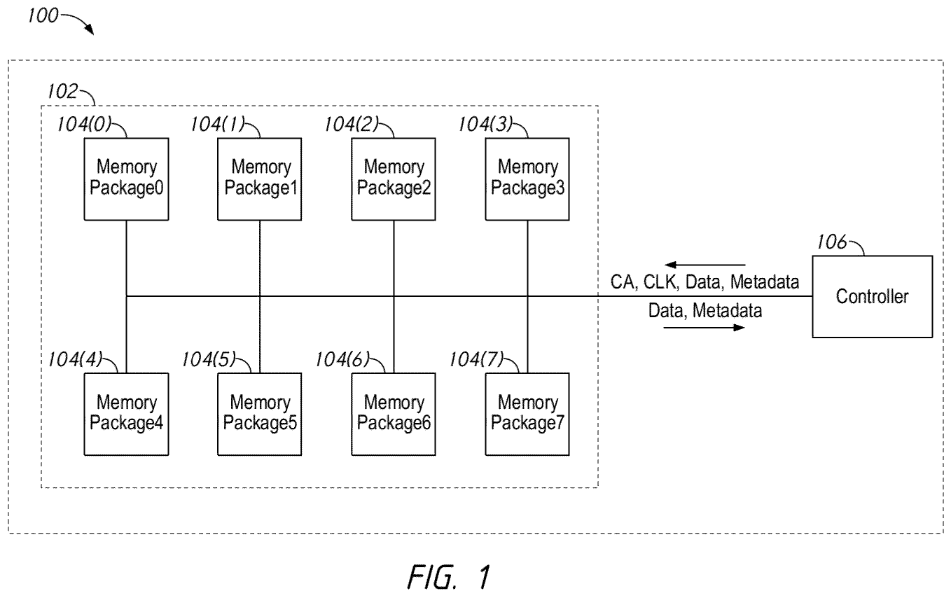

FIG. 1 illustrates a block diagram of at least a portion of an example system 100 according to an embodiment of the disclosure. For example, the system 100 can be a computing system. The system 100 includes a memory module 102 and a controller 106 in communication with the memory module 102. In some embodiments, the controller 106 may be included in a processor (not shown) or in communication with a processor. The memory module 102 may include one or more memory packages. In the embodiment shown in FIG. 1, there are eight memory packages 104(0)-104(7). However, in other embodiments, there may be more or fewer memory packages (e.g., one device, two devices, four devices, sixteen devices). In certain embodiments, the memory module 102 may be a dual in-line memory module (DIMM). In other embodiments, the components shown in FIG. 1 may represent only half of the DIMM (e.g., one of the two channels). In other words, the memory module 102 may include sixteen memory packages.

According to an embodiment, each memory package 104(0)-104(7) may include one or more memory devices and an additional die. A memory device is also referred to herein as a memory die. The additional die may include components that facilitate communication with the controller 106 and/or host system. In some embodiments, the additional die may include components that facilitate communication between memory packages 104(0)-104(7). The memory devices can be stacked on the additional die in some examples, although other embodiments are not limited to this configuration.

The controller 106 can provide signals such as commands, addresses, clock signals and/or data (e.g., data, metadata, or both) to one or more of the memory packages 104(0)-104(7) and receive signals such as data, metadata, or both from one or more of the memory packages 104(0)-104(7). According to some embodiments, the controller 106 may provide and receive signals from a memory die via the additional die. In some embodiments, the memory packages 104(0)-104(7) may be x16 or x32 memory devices. That is, either sixteen (16) or thirty-two (32) DQ terminals (e.g., pins) may be active. In some embodiments, the memory packages 104(0)-104(7) may support both x16 and x32 operations. In certain embodiments, whether the memory packages 104(0)-104(7) operate in x4 or x8 mode may be based, at least in part, on values stored in mode registers (not shown) of the memory packages 104(0)-104(7). In some embodiments, the memory packages 104(0)-104(7) may be x4, x8, or x64 memory packages.

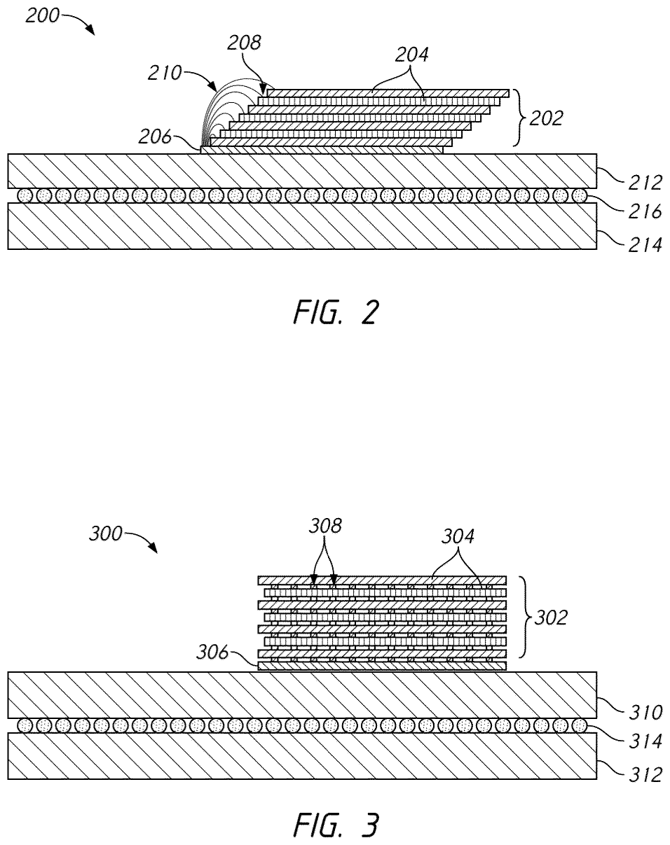

FIG. 2 illustrates an example of a multi-die device 200 according to an embodiment of the disclosure. The multi-die device 200 may include a stack 202 of memory devices 204 stacked on an additional die 206. Other embodiments are not limited to the particular number of memory devices 204 shown in FIG. 2. For example, the stack 202 may include one to sixteen memory devices 204. Further, while one additional die 206 is shown in FIG. 2, in some embodiments, there may be multiple additional dies 206 per stack 202. For example, the stack 202 can include two additional dies 206. In some embodiments, the stack 202 may be included in one or more memory packages (e.g., one or more of the memory packages 104(0)-104(7) of FIG. 1).

The memory devices 204 and the additional die 206 may be stacked in a staggered manner, providing a “shingle-stack” configuration for the stack 202 as shown in FIG. 2. However, the memory devices 204 and the additional die 206 may be stacked in other arrangements, such as a staggered configuration. The memory devices 204 and/or the additional die 206 may be attached to one another. In some embodiments, the memory devices 204 are attached to one another by an adhesive epoxy.

The memory devices 204 and/or the additional die 206 may include a pad formation area, a peripheral circuit area, and memory cell array areas that include memory cells, signal lines and circuits (not shown). Example circuits and signal lines include, but are not limited to, sense amplifier circuits, address decoder circuits, data input/output lines, etc. The peripheral circuit area may include various circuits and signal lines for performing various operations. For example, the peripheral circuit area may include command and address input circuits, address and command decoders, clock circuits, power circuits, and input/output circuits. The peripheral circuit area may also include terminals coupled to various circuits of the memory devices 204 and/or the additional die 206.

The pad formation area may include bond pads (not shown) disposed along one or more edges of the memory devices 204 and/or the additional die 206. The bond pads may be coupled to the terminals of the memory devices 204 and/or the additional die 206 and represent external terminals of the memory devices 204 and/or the additional die 206. For example, the bond pads may include data terminals, command and address terminals, clock terminals, and/or power supply terminals.

Circuits included in the memory cell array area and/or circuits of the peripheral circuit area may be coupled to one or more bond pads included in the pad formation area. Various circuits of the memory devices 204 and/or the additional die 206 may be coupled to the terminals. Conductive structures may be used to couple the terminals to one or more of the bond pads. As a result, the circuits coupled to the terminals are also coupled to the bond pads. The conductive structures may extend from locations of the terminals included in the memory cell array area and/or the peripheral circuit area to the pad formation area.

The memory devices 204 may be offset from one another to allow edge regions 208 of the memory devices 204 to be exposed. The exposed edge regions 208 may include the bond pads to which conductors 210 may be coupled. In some embodiments of the disclosure, the bond pads of the edge regions 208 may be conductive pads. The bond pads may be coupled to terminals of the respective memory device 204. In some embodiments, the conductors 210 are bond wires. While the conductors 210 in FIG. 2 are shown coupling all of the memory devices 204 to the additional die 206, the conductors 210 may be coupled in other configurations. For example, the conductors 210 may couple adjacent memory devices 204 to one another, and the lowest or bottom memory device 204 may be coupled to the additional die 206 by the conductors 210 in a “daisy chain” configuration.

The stack 202 may be attached to a substrate 212. For example, the stack 202 may be attached to the substrate 212 by an adhesive epoxy. The substrate 212 may be an interposer, a printed circuit board, or another type of substrate. The substrate 212 may include conductive signal lines to route signals along the substrate 212, for example, to and from the memory devices 204 and/or the additional die 206. The substrate 212 can be electrically coupled to the additional die 206 through electrical connectors (not shown), such as a flip chip ball grid array and/or wire bonding.

Other circuits may also be attached to the substrate 212 and coupled to the conductive signal lines of the substrate 212. The other circuits attached to the substrate 212 may be coupled, for example, to the memory devices 204 and/or the additional die 206 through the conductive signal lines of the substrate 212 and through conductors coupled to the conductive signal lines and the bond pads of the memory devices 204 and/or the additional die 206. In some embodiments, the substrate 212 may be included in a memory module (e.g., the memory module 102 of FIG. 1).

The substrate 212 can be coupled to another substrate 214 through conductive connectors 216. Although the conductive connectors 216 are shown as a ball grid array, other embodiments are not limited to this configuration. The substrate 214 may be any type of substrate. For example, the substrate 214 may be a package substrate.

FIG. 3 illustrates another example of a multi-die device 300 according to an embodiment of the disclosure. The multi-die device 300 may include a stack 302 of memory devices 304 stacked on an additional die 306. Other embodiments are not limited to the particular number of memory devices 304 in the stack 302 shown in FIG. 3. For example, the stack 302 may include one to sixteen memory devices 304. Further, while one additional die 306 is shown in FIG. 3, other embodiments can include multiple additional dies 306 per stack 302. For example, the stack 302 may include two additional dies 306. In some embodiments, the stack 302 may be included in one or more memory packages (e.g., the memory packages 104(0)-104(7)).

Similar to the embodiment of FIG. 2, the memory devices 304 and/or the additional die 306 may include a pad formation area, a peripheral circuit area, and memory cell array areas (not shown) that include memory cells, signal lines and circuits. For example, the circuits and the signal lines can include sense amplifier circuits, address decoder circuits, data input/output lines, etc. The peripheral circuit area may include various circuits and signal lines for performing various operations. For example, the peripheral circuit area may include command and address input circuits, address and command decoders, clock circuits, power circuits, and input/output circuits. The peripheral circuit area may also include terminals coupled to various circuits of the memory devices 304 and/or the additional die 306.

The memory devices 304 and the additional die 306 may be stacked in an aligned manner, such that the edges of the memory devices 304 are substantially aligned. When the additional die 306 is a similar dimension to the memory devices 304, the additional die 306 may be substantially aligned with the memory devices 304 as well, as shown in FIG. 3. However, the memory devices 304 and the additional die 306 may be stacked in other configurations such as a staggered configuration.

In contrast to the stack 202 shown in FIG. 2, the memory devices 304 and/or the additional die 306 are electrically coupled to one another by through silicon vias (TSVs) 308. In some embodiments, instead of or in addition to pad formation areas, the memory devices 304 and/or the additional die 306 may include TSV formation areas. The memory devices 304 and/or the additional die 306 may be physically attached to one another by additional mechanisms (e.g., not just the TSVs). In some embodiments, the memory devices 304 and the additional die 306 are attached to one another by an adhesive epoxy.

The stack 302 may be attached to a substrate 310. For example, the stack 302 may be attached to the substrate 310 by an adhesive epoxy. The substrate 310 may be an interposer, a printed circuit board, or another type of substrate. The substrate 310 may include conductive signal lines to route signals along the substrate 310, for example, to and from the memory devices 304 and/or the additional die 306. Other circuits may also be attached to the substrate 310 and coupled to the conductive signal lines of the substrate 310. As a result, the other circuits attached to the substrate 310 may be electrically coupled, for example, to the memory devices 304 and/or the additional die 306. In some embodiments, the substrate 310 may be included in a memory module (e.g., the memory module 102 of FIG. 1).

The substrate 310 can be coupled to another substrate 312 through conductive connectors 314. Although the conductive connectors 314 are shown as a ball grid array, other embodiments are not limited to this configuration. The substrate 312 may be any type of substrate. For example, the substrate 312 may be a package substrate.

In some embodiments, the memory devices 204, 304 and/or the additional die 206, 306 may include redundant memory. In certain embodiments, the additional die 206, 306 is a memory device substantially similar to the memory devices 204, 304. In some embodiments, the memory devices 204, 304 may have certain logic circuits disabled and/or bypassed, and the additional die 206, 306 has such logic circuits enabled and acts as a “target” or “master” die. In some embodiments, the additional die 206, 306 is a different device with different components than the memory devices 204, 304. According to embodiments of the present disclosure, the additional die 206, 306 may include buffers for buffering and/or arranging data received from the memory devices 204, 304 prior to providing to a controller and arranging data received from the controller prior to providing to the memory devices 204, 304.

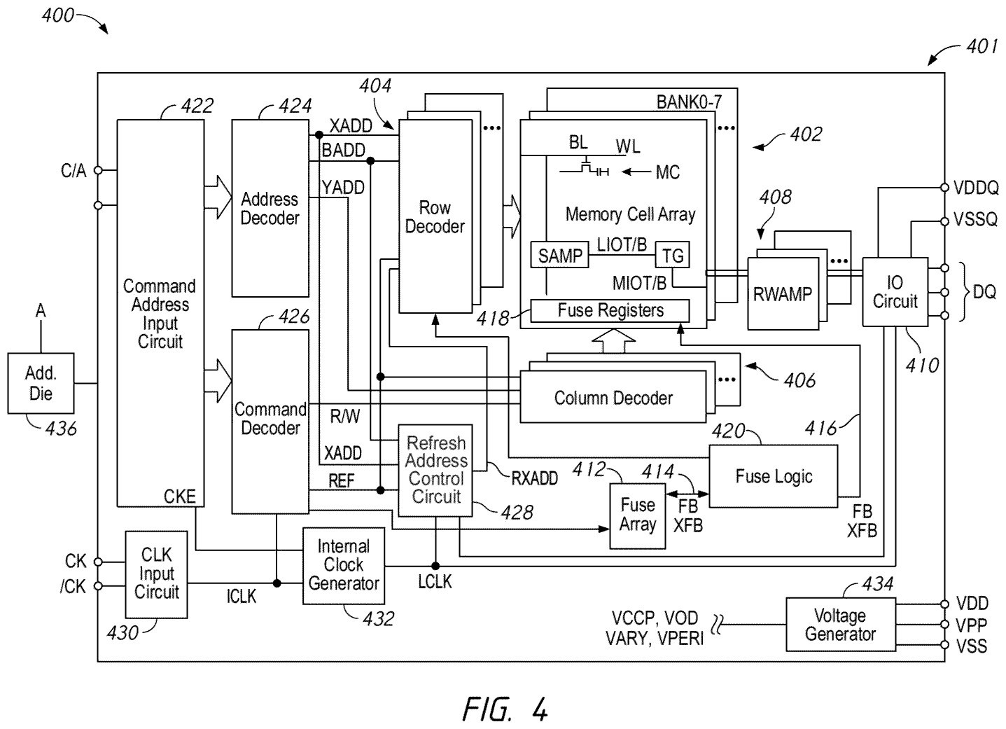

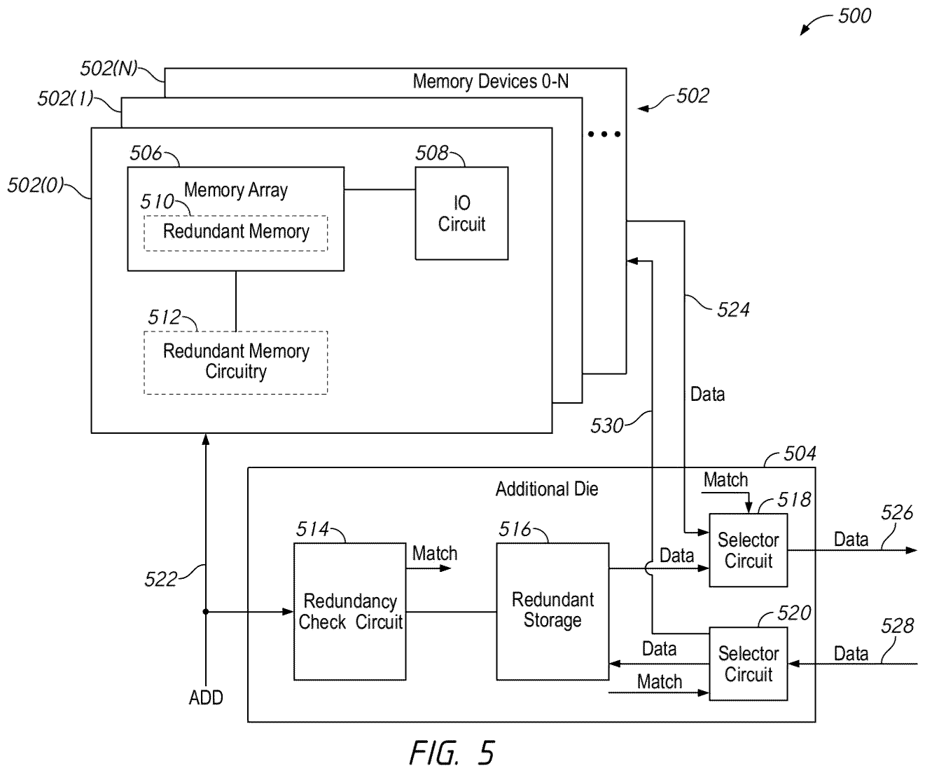

FIG. 4 illustrates a block diagram of an example semiconductor device 400 according to an embodiment of the disclosure. The semiconductor device 400 may include a memory device 401. The memory device 401 can include, without limitation, a dynamic random-access memory (DRAM), a double data rate (DDR) memory, a DDR5 or a DDR6 memory device, or other type of memory. In certain embodiments, each memory package 104(0)-104(7) of FIG. 1 can include one or more semiconductor devices 400. In some embodiments, the memory devices 204 of FIG. 2 and/or the memory devices 304 of FIG. 3 may each include the memory device 401.

The memory device 401 includes a memory array 402. The memory array 402 includes a plurality of memory banks BANK0-7. More or fewer memory banks may be included in the memory array 402 of other embodiments. In some embodiments, the memory banks may be arranged into bank groups. For example, a memory device may include sixteen or thirty-two total memory banks that are divided into two, four, eight or sixteen bank groups with two banks or four banks per bank group.

Each memory bank BANK0-7 includes a plurality of word lines WL, a plurality of bit lines BL and/BL (collectively referred to as BL), and a plurality of memory cells MC arranged at intersections of the plurality of word lines WL and the plurality of bit lines BL. The selection of the word lines WL is performed by a row decoder 404 and the selection of the bit lines BL is performed by a column decoder 406. In the embodiment of FIG. 4, the row decoder 404 includes a respective row decoder for each memory bank and the column decoder 406 includes a respective column decoder for each memory bank.

The bit lines are coupled to a respective sense amplifier (SAMP). Read data from the bit line BL is amplified by the sense amplifier SAMP and transferred to one or more read/write amplifiers 408 over complementary local data lines (LIOT/B), transfer gate (TG), and complementary main data lines (MIOT/B). Conversely, write data outputted from the one or more read/write amplifiers 408 is transferred to the sense amplifier SAMP over the complementary main data lines MIOT/B, the transfer gate TG, and the complementary local data lines LIOT/B, and written in the memory cell MC coupled to the bit line BL. The one or more read/write amplifiers (RWAMP) 408 may be coupled to an input/output (IO) circuit 410. The input/output circuit 410 can be coupled to one or more external terminals of the semiconductor device 400.

The memory device 401 can also include a fuse array 412, which contains a plurality of non-volatile storage elements that may store information about addresses in the memory array 402 (e.g., row repair information, column repair information). For example, the fuse array 412 can include fuses and/or anti-fuses. Each fuse may be in a first state where it is conductive until the fuse is ‘blown’ to make the fuse insulating instead. Each anti-fuse may be in a first state which is non-conductive until the anti-fuse is blown to make the anti-fuse conductive instead. Each fuse/anti-fuse may permanently change when it is blown. Each fuse/anti-fuse may be considered to be a bit, which is in one state before it is blown, and permanently in a second state after it's blown. For example, a fuse may represent a logical low before it is blown and a logical high after it is blown, while an anti-fuse may represent a logical high before it is blown and a logical low after it is blown. It should be understood that discussions of fuses as used herein may generally refer to either fuses or anti-fuses and that embodiments may use fuses, anti-fuses, or a combination thereof in the fuse array 412.

Specific groups of fuses/anti-fuses may be represented by a fuse bank address (FBA), which may specify the physical location of each of the fuses/anti-fuses in the group within the fuse array 412. The group of fuses/anti-fuses associated with a particular FBA may in turn encode an address associated with one or more memory cells of the memory array 402. For example, the state of a group of fuses/anti-fuses may represent a row address XADD or a column address YADD. FBAs can be provided to the fuse array 412 on a fuse bus 414 and in response, the address information in the fuse array 412 may be ‘scanned’ out along a fuse bus 416 to fuse registers 418. Each fuse register 418 may be associated with a particular word line of the memory array 402. In some embodiments, the redundant rows/columns of the memory array 402 (e.g., the rows/columns designated for use in repair operations) may be associated with one of the fuse registers 418. The address stored in a given group of fuses/anti-fuses (e.g., a group specified by an FBA) may be scanned out from the fuse array 412 along the fuse buses 414, 416 and latched by a particular fuse register 418. A fuse logic circuit 420 may determine which address broadcast along the fuse bus 416 is latched in which fuse register 418. In this manner, an address stored in the fuse array 412 may be associated with a particular row or column of the memory array 402. When an incoming memory address matches the address stored in the fuse register 418, it may then direct access commands to the memory row/column associated with that fuse register 418.

The fuse registers 418 may each contain a number of fuse latches, each of which stores a bit of the stored memory row or memory bank address. Since row addresses XADD and column addresses YADD may be different lengths, the fuse registers 418 associated with redundant rows may have a different number of fuse latches than the fuse registers 418 associated with redundant columns. Each of the fuse registers 418 may be coupled to a fuse match circuit (not shown), which compares the incoming memory row address as part of an access operation to the address stored in the fuse register 418 to determine if there is a match. If there is a match, the redundant memory row associated with the fuse register 418 may be activated.

Some components of the match circuits, as well as other control logic of the fuse registers 418 may be shared between multiple fuse registers 418. For example, in some embodiments, match circuits may be shared by a number of different fuse registers 418. In some embodiments, a dynamic logic circuit may manage which of the fuse registers 418 coupled to a match circuit is active to provide the address stored in that fuse registers 418 for a comparison operation to determine if an accessed memory line address matches the stored address. In some embodiments, the dynamic logic circuit may also manage timing of the comparison operation.

The semiconductor device 400 may employ a plurality of external terminals that include command and address (C/A) terminals coupled to a command/address bus to receive command and address signals, clock terminals to receive clock signals CK and /CK, data terminals DQ to provide data, and power supply terminals VDD, VPP, VDDQ, VSS, and VSSQ. In one embodiment, VDD, VPP, VDDQ may be power supply potential terminals and VSSQ and VSS may be ground reference terminals. The C/A terminals may be supplied with memory addresses from, for example, a host or a controller (e.g., the controller 106 of FIG. 1). The memory addresses supplied to the C/A terminals are transferred, via a command/address input circuit 422, to an address decoder 424. The address decoder 424 receives the address signals and supplies a decoded row address signal XADD to the row decoder 404, and a decoded column address signal YADD to the column decoder 406. The address decoder 424 also receives the bank address signal BADD and supplies the bank address signal to the row decoder 404 and the column decoder 406.

The C/A terminals may further be supplied with command signals from, for example, the host or the controller. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The command signals may be provided as internal command signals to a command decoder 426 via the command/address input circuit 422. The command decoder 426 includes circuits to decode the internal command signals to generate various internal signals and commands for performing operations, for example, a row activation signal (ACT) to select a word line. Another example may be providing internal signals to enable circuits for performing operations, such as control signals to enable signal input buffers that receive clock signals.

The C/A terminals may receive an access command which is a read command. When a read command is received, and a bank address, the row address, and a column address are timely supplied as part of the read operation, read data is read from memory cells in the memory array 402 corresponding to the row address and column address. For example, the row decoder 404 may access the word line associated with the fuse register 418 that stores an address which matches XADD. The read command is received by the command decoder 426, which provides internal commands so that read data from the memory array 402 is provided to the read/write amplifiers 408. The row decoder 404 may match the address XADD to an address stored in the fuse register 418, and then may access the physical row associated with that row fuse register 418. The read data is output to outside from the data terminals DQ via the input/output circuit 410.

The C/A terminals may receive an access command which is a write command. When the write command is received, and a bank address, the row address, and a column address are timely supplied as part of the write operation, and write data supplied through the DQ terminals is written to a memory cell in the memory array 402 corresponding to the row address and column address. The write command is received by the command decoder 426, which provides internal commands so that the write data is received by data receivers in the input/output circuit 410. The row decoder 404 may match the address XADD to an address stored in the fuse register 418, and then access the physical row associated with that row fuse register 418. Write clocks may also be provided to the external clock terminals for timing the receipt of the write data by the data receivers of the input/output circuit 410. The write data is supplied via the input/output circuit 410 to the read/write amplifiers 408, and by the read/write amplifiers 408 to the memory array 402 to be written into the memory cell MC.

The semiconductor device 400 may also receive commands causing it to carry out a self-refresh operation or a refresh operation. The refresh signal REF may be a pulse signal which is activated when the command decoder 426 receives a signal which indicates a self-refresh or a refresh command. In some embodiments, the refresh and self-refresh commands may be externally issued to the semiconductor device 400. In some embodiments, the self-refresh command may be periodically generated by a component of the memory device 401. In some embodiments, when an external signal indicates a self-refresh entry command, the refresh signal REF may also be activated. The refresh signal REF may be activated once immediately after command input and thereafter may be cyclically activated at desired internal timing. Thus, refresh operations may continue automatically. A self-refresh exit command may cause the automatic activation of the refresh signal REF to stop and return to an IDLE state.

The refresh signal REF is supplied to the refresh address control circuit 428. The refresh address control circuit 428 supplies a refresh row address RXADD to the row decoder 404, which may refresh a word line WL indicated by the refresh row address RXADD. The refresh address control circuit 428 may control the timing of the refresh operation and may generate and provide the refresh address RXADD. The refresh address control circuit 428 may be controlled to change details of the refreshing address RXADD (e.g., how the refresh address is calculated, the timing of the refresh addresses), or may operate based on internal logic. In some embodiments, the refresh address control circuit 428 may perform both auto-refresh operations, where the word lines of the memory array 402 are refreshed in a sequence, and targeted refresh operations, where specific word lines of the memory are targeted for a refresh out of sequence from the auto-refresh operations.

The clock terminals are supplied with external clocks CK and /CK that are provided to a clock input circuit 430. The external clocks may be complementary differential signals. When enabled, input buffers (not shown) included in the clock input circuit 430 pass the external clock signals. For example, an input buffer passes the CK and /CK signals when enabled by a CKE signal from the command/address input circuit 422. The clock input circuit 430 may use the external clock signals passed by the enabled input buffers to generate an internal clock ICLK. The ICLK clock is provided to the command decoder 426 and to an internal clock generator 432. The internal clock generator 432 provides various internal clocks LCLK based on the ICLK clock. The LCLK clocks may be used for timing operations of various internal circuits. The internal data clocks LCLK are provided to the input/output circuit 410 to time operation of circuits included in the input/output circuit 410, for example, to data receivers to time the receipt of write data.

The power supply terminals are supplied with potentials VDD, VPP and VDDQ. The potentials VDD and VPP are supplied to an internal voltage generator circuit 434, and the potential VDDQ is supplied to the input/output circuit 410. The internal voltage generator circuit 434 generates various internal potentials VCCP, VOD, VARY, VPERI. The internal potential VCCP is mainly used in the row decoder 404, the internal potentials VOD and VARY are mainly used in the sense amplifiers included in the memory array 402, and the internal potential VPERI is used in many other circuit blocks.

The power supply terminals are also supplied with potentials VSSQ and VSS. The potentials VSSQ and VSS are reference potentials (e.g., ground) provided to the input/output circuit 410 and the internal power voltage generator circuit 434, respectively. The potentials VDDQ and VSSQ supplied to the power supply terminals may be the same potentials as the potentials VDD, VPP and VSS supplied to the power supply terminals in an embodiment of the disclosure. The potentials VDDQ and VSSQ supplied to the power supply terminals may be different potentials from the potentials VDD or VPP and VSS supplied to the power supply terminals in another embodiment of the disclosure. The potentials VDDQ and VSSQ are used for the input/output circuit 410 so that power supply noise generated by the input/output circuit 410 does not propagate to the other circuit blocks.

The semiconductor device 400 may also include an additional (Add.) die 436. The additional die 436 can receive the memory addresses (A) from the host or the controller. As will be described in more detail later, the additional die 436 may include various components, such as redundant storage. The redundant storge can be used as redundant failure protection.

FIG. 5 illustrates a block diagram of a portion of an example memory package 500 according to an embodiment of the disclosure. The memory package 500 includes a plurality of memory devices (0-N) 502 and an additional die 504. More or fewer memory devices 502 may be included in the memory package 500 of other embodiments. In some embodiments, the memory package 500 may be implemented as the multi-die device 200 of FIG. 2 and/or the multi-die device 300 of FIG. 3. Each memory device can, in certain embodiments, include the memory device 401 of FIG. 4.

For simplicity, FIG. 5 is described in conjunction with one memory device 502(0). However, the description applies to each of the plurality of memory device 502(0)-502(N). The memory device 502(0) may include one or more memory arrays (collectively memory array 506) and an input/output circuit 508. The memory device 502(0) can include additional components, such as some or all of the components shown in the memory device 401 of FIG. 4. For example, the memory device 502(0) may include a command/address input circuit 422, an address decoder 424, a command decoder 426, a row decoder 404, a column decoder 406, and read/write amplifiers 408. Because FIG. 5 is described in conjunction with a read operation and a write operation, the additional components of the memory device 502(0) are omitted for brevity.

The memory device 502(0) may optionally include redundant memory 510 and redundant memory circuitry 512. In one embodiment, the redundant memory 510 is additional rows of memory cells and fuse registers and the redundant memory circuitry 512 includes a fuse array and fuse logic. For example, in some embodiments, the redundant memory circuitry 512 may include fuse array 412 and/or fuse logic 414. The redundant memory 510 can be used for repair operations. As described earlier, data associated with one or more addresses in the memory array 506 that are associated with defective memory cells are remapped to addresses in the redundant memory 510 such that memory cells in the redundant memory 510 are accessed instead of the defective memory cells. Accordingly, data may be read from or written to the memory cells in the redundant memory 510 instead of the defective memory cells in the memory array 510.

The additional die 504 may include a redundancy check circuit 514, redundant storage 516, a selector circuit 518, and a selector circuit 520. In one embodiment, the redundant storage 516 in the additional die 504 may be in addition to, or supplement, the redundant memory 510 in the memory device 502(0). In another embodiment, the redundant memory 510 is omitted from the memory device 502(0) and the redundant storage 516 is included in the additional die 504. The redundant storage 516 can include any type of volatile or non-volatile storage elements. For example, the redundant storage 516 may include SRAM storage elements, latches, embedded DRAM, or any other type of storage elements. In some embodiments, the additional die 504 may include the additional die 206 of FIG. 2, the additional die 306 of FIG. 3, and/or the additional die 436 of FIG. 4. In certain embodiments, the additional die 504 may be a memory device, such as the memory device 401 of FIG. 4, or include at least some components that are the same as or similar to components included in the memory device 401. The plurality of memory devices 502 and the additional die 504 can be included in a memory package or a multi-die device. For example, the plurality of memory devices 502 and the additional die 504 may be included in the memory packages 104(0)-(7) of FIG. 1, the multi-die device 200 of FIG. 2, and/or multi-die device 300 of FIG. 3.

An output of the redundancy check circuit 514 is coupled to an input of the redundant storage 516, and an output of the redundant storage 516 is coupled to an input of the selector circuit 518. Another input of the selector circuit 518 is coupled to each of the plurality of memory devices 502. An output of the selector circuit 520 is coupled to an input of the redundant storage 516. Another output of the selector circuit 510 is coupled to each of the plurality of memory devices 502. In some embodiments, the selector circuit 518 is a multiplexer and the selector circuit 520 is a demultiplexer. Other embodiments may use different types of circuits for the selector circuits 518, 520. A match signal output from the redundancy check circuit 514 can function as a control signal for the selector circuits 518, 520.

When the memory array 506 does not include the redundant memory 510 and the redundant memory circuitry 512, and memory cells in the memory array 506 are defective or become defective, the addresses associated with the defective memory cells may be remapped to the redundant storage 516 of the additional die 504. Information associated with the remapped addresses of the memory array 506 may be stored in the redundancy check circuit 514. In one embodiment, the memory device 502(0) and the additional die 504 each receive an address for the memory array 506 for access operations and the additional die 504 is configured to determine whether the address is associated with defective memory cells in the memory array 506. If the address is not associated with defective memory cell(s) in the memory array 506, the memory cell(s) in the memory array 506 that are associated with the address are accessed. When the address is associated with one or more defective memory cells in the memory array 506, memory cells in the redundant storage 516 are accessed using a remapped address that is associated with the address.

Continuing with this example, when a read operation on the memory array 506 is to be performed, the memory device 502(0) and the additional die 504 each receive the address for the read operation on signal line 522. The redundancy check circuit 514 is configured to determine if the address is associated with one or more defective memory cells in the memory array 506 on the memory device 502(0). Based on a determination that the address is not associated with one or more defective memory cells in the memory array 506, the redundancy check circuit 514 outputs a Match signal having a first signal level (e.g., a low or “0”). Data is read out of the memory array 506 and output onto signal line 524 (via the input/output circuit 508) based on the address, and the read data is received by the selector circuit 518 on the additional die 504. Because the signal level of the Match signal is at the first signal level, the selector circuit 528 provides the read data output from the memory device 502(0) on signal line 526.

Alternately, based on a determination that the address is associated with one or more defective memory cells in the memory array 506, the redundancy check circuit 514 outputs the Match signal at a second signal level (e.g., a high or “1”). Data is read out of the redundant storage 516 on the additional die 504 based on the address, and the read data is received by the selector circuit 518. Because the signal level of the match signal is at the second signal level, the selector circuit 528 provides the read data output from the redundant storage 516 on signal line 526.

When a write operation to the memory array 506 is to be performed, the memory device 502(0) and the additional die 504 receive the address for the write operation on signal line 522. The write data is received by the selector circuit 520 on signal line 528. The redundancy check circuit 514 is configured to determine if the address is associated with one or more defective memory cells in the memory array 506. Based on a determination that the address is not associated with one or more defective memory cells in the memory array 506, the redundancy check circuit 514 outputs the Match signal at the first signal level, enabling the selector circuit 520 to output the write data onto signal line 530. The write data is written to one or more memory cells in the memory array 506 that correspond to the address.

Alternately, based on a determination that the address is associated with one or more defective memory cells in the memory array 506, the redundancy check circuit 514 outputs the Match signal at the second signal level, enabling the selector circuit 520 to provide the write data to the redundant storage 516. The write data is written to the redundant storage 516 based on the address.

When the memory array 506 includes the redundant memory 510 and the redundant memory circuitry 512 in addition to the additional die 504 including the redundant storage 516, and memory cells in the memory array 506 are defective or become defective, the addresses associated with the defective memory cells may be remapped to addresses for the redundant memory 510 or the redundant storage 516. For example, an address can be remapped to one of the redundant memory 510 or the redundant storage 516 based on available storage space in the redundant memory 510 and the redundant storage 516. When the address is remapped to the redundant memory 510, information associated with the remapped addresses may be stored in the redundant memory circuitry 512. When the address is remapped to the redundant storage 516, information associated with the remapped addresses may be stored in the redundancy check circuit 514. In some embodiments, each of the plurality of memory devices 502 and the additional die 504 receive an address for the memory array 506 for access operations and each of the plurality of memory devices 502 and the additional die 504 determine whether the address is associated with one or more defective memory cells in the memory array 506. If the address is not associated with defective memory cell(s) in the memory array 506, the memory cell(s) in the memory array 506 that are associated with the address are accessed. When the address is associated with one or more defective memory cells in the memory array 506, memory cells in the redundant memory 510 or in the redundant storage 516 are accessed based on the information stored in the redundant memory circuitry 512 and the redundancy check circuit 514, respectively.

Continuing with this example, when a read operation on the memory array 506 is to be performed, the memory device 502(0) and the additional die 504 each receive the address for the read operation on signal line 522. The redundant memory circuitry 512 and the redundancy check circuit 514 are both configured to determine if the address is associated with one or more defective memory cells in the memory array 506. Based on a determination by the redundancy check circuit 514 that the address is not associated with one or more defective memory cells in the memory array 506, the redundancy check circuit 514 outputs a Match signal having the first signal level. Based on a determination by the redundant memory circuitry 512 that the address is not associated with one or more defective memory cells in the memory array 506, data is read out of the memory array 506 based on the address and output on signal line 524 (via the input/output circuit 508). The read data is received by the selector circuit 518 on the additional die 504. Because the signal level of the Match signal is at the first signal level, the selector circuit 528 provides the read data output from the memory array 506 on signal line 526.

Alternately, based on a determination by the redundant memory circuitry 512 that the address is associated with one or more defective memory cells in the memory array 506, data is read out of the redundant memory 510 and output on the signal line 524 (via the input/output circuit 508). Further, based on a determination by the redundancy check circuit 514 that the address is not associated with one or more defective memory cells in the memory array 506, the redundancy check circuit 514 outputs the Match signal at the first signal level. The read data read from the redundant memory 510 is received by the selector circuit 518 on the additional die 504. Because the signal level of the Match signal is at the first signal level, the selector circuit 528 provides the read data output from the redundant memory 510 on the signal line 526.

Alternately, based on a determination by the redundancy check circuit 514 that the address is associated with one or more defective memory cells in the memory array 506, data is read out of the redundant storage 516 based on the address. Further, the redundancy check circuit 514 outputs the Match signal at the second signal level. The read data from the redundant storage 516 is received by the selector circuit 518 on the additional die 504. In some embodiments, data may be read out of the memory array 506 based on the address, output onto the signal line 524 (via the input/output circuit 508), and received by the selector circuit 518. Alternately, the data read out of the memory array 506 may be disregarded or deleted. However, because the signal level of the Match signal is at the second signal level, the selector circuit 528 provides the read data output from the redundant storage 516 on the signal line 526.

When a write operation on the memory array 506 is to be performed, the memory device 502(0) and the additional die 504 each receive the address for the read operation on signal line 522. The data to be written to the memory array 506 is received by the selector circuit 520 on the signal line 528. The redundancy check circuit 514 and the redundant memory circuitry 512 are both configured to determine if the address is associated with one or more defective memory cells in the memory array 506. Based on a determination by the redundancy check circuit 514 that the address is not associated with one or more defective memory cells in the memory array 506, the redundancy check circuit 514 outputs the Match signal at the first signal level. Because the Match signal is at the first signal level, the selector circuit 520 outputs the write data onto the signal line 530, where the write data is received by the input/output circuit 508. Based on a determination by the redundant memory circuitry 512 that the address is not associated with one or more defective memory cells in the memory array 506, the write data is written to the memory array 506 based on the address. Alternately, based on a determination by the redundant memory circuitry 512 that the address is associated with one or more defective memory cells in the memory array 506, the write data is written to the redundant memory 510 based on the address.

Alternately, based on a determination by the redundancy check circuit 514 that the address is associated with one or more defective memory cells in the memory array 506, the redundancy check circuit 514 outputs the Match signal at the second signal level. Because the Match signal is at the second signal level, the selector circuit 520 provides the write data to the redundant storage 516, where the data is written to the redundant storage 516.

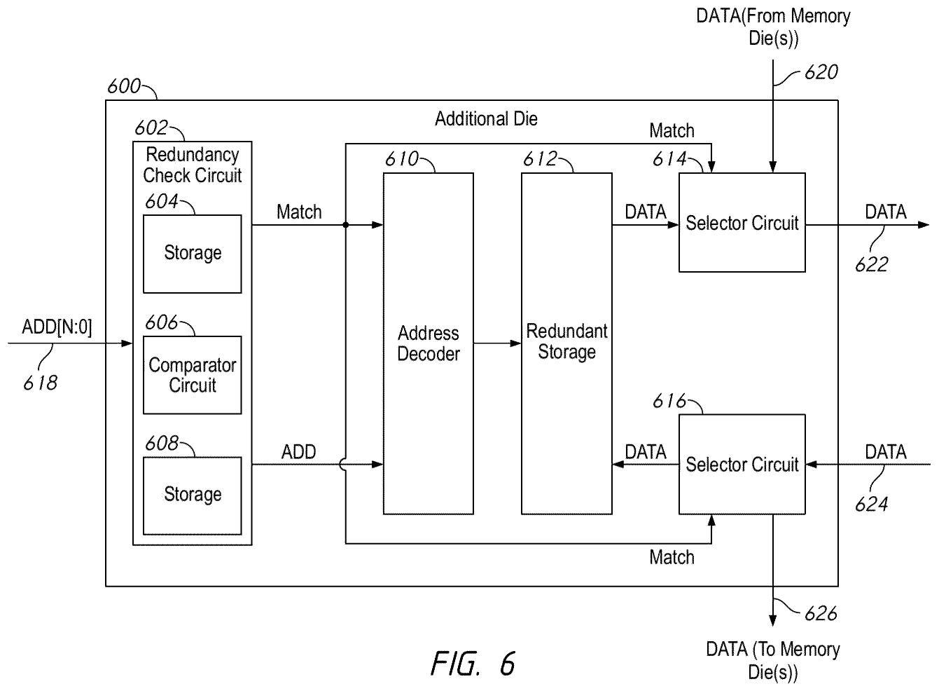

FIG. 6 illustrates a block diagram of an example additional die 600 according to an embodiment of the disclosure. The additional die 600 can include the additional die 504 shown in FIG. 5 in some embodiments. A redundancy check circuit 602 includes storage 604, a comparator circuit 606, and storage 608. Although the storages 604, 608 are shown as separate storage, the storages 604, 608 can be implemented as one storage in some embodiments. The additional die 600 can further include an address decoder 610, redundant storage 612, a selector circuit 614, and a selector circuit 616. The Match signal is received by the selector circuit 614 and the selector circuit 616 and functions as a control signal for the selector circuits 614, 616.

An address (ADD [N:0]) for an access operation to one or more memory cells in a memory array is received on signal line 618. The address ADD may, in some embodiments, be received from a controller or a host, such as the controller 106 of FIG. 1. For example, the access operation can be a read operation or a write operation. The storage 604 is configured to receive and store the address ADD in memory elements. The memory elements may be volatile or non-volatile memory elements. In one embodiment, the memory elements are latches.

The storage 608 is configured to store one or more addresses that are associated with defective memory cells (“defective addresses”) and the remapped addresses associated with the defective addresses. In certain embodiments, the defective addresses and the remapped addresses can be stored in a look-up table in the storage 608.

The comparator circuit 606 is configured to compare the address ADD stored in the storage 604 with the addresses stored in the storage 608. The comparator circuit 606 outputs the Match signal at the first signal level when the address ADD does not match an address in the storage 608, and outputs the Match signal at the second signal level when the address ADD matches an address in the storage 608. The address decoder 610 receives the Match signal and the address ADD. When the Match signal is at the second signal level, the address decoder 610 decodes the address ADD to access the redundant storage 612. Data is output from the redundant storage 612 and is received by the selector circuit 614. The selector circuit 614 can also receive data from one or more memory devices on signal line 620. The selector circuit 614 outputs the data output from the redundant storage 612 or the data output from the memory array on signal line 622 based on the signal level of the Match signal. The selector circuit 616 receives data on signal line 624 and provides the data to the redundant storage 612 or to one or more memory dies on signal line 624 based on the signal level of the Match signal.

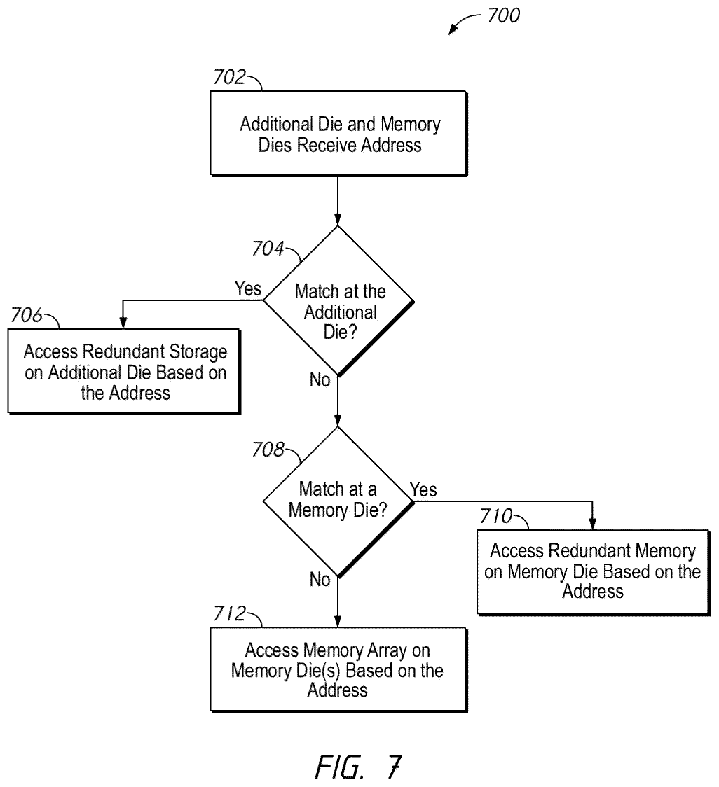

FIG. 7 illustrates a flowchart of an example method 700 according to an embodiment of the disclosure. The method 700 can be performed in whole or in part by an additional die with redundant storage and by one or more memory dies with redundant memory and redundant memory circuitry, such as additional die 436, 504, and/or 600 of FIGS. 4-6 and memory die 401 and/or 502 of FIGS. 4-5. At block 702, an additional die and the one or more memory dies receive an address for an access operation for at least one memory array on the memory die(s). A determination is made at block 704 as to whether the received address is associated with (e.g., matches) an address associated with one or more defective memory cells in the memory array. In some embodiments, the determination may be made by a redundancy check circuit on the additional die such as redundancy check circuit 514 and/or 602 of FIGS. 5-6. The method may include determining, at the additional die, if the received address matches one or more addresses stored at the additional die that are associated with one or more defective memory cells in a memory array on at least one memory die. The method can include determining, at the additional die, a remapped address for the received address when the received address matches an address that is associated with one or more defective memory cells. The method may include accessing a lookup table stored in one or more storages (e.g., 604 in FIG. 6) at the additional die to determine whether the received address matches one or more addresses that are associated with the one or more defective memory cells. The method can include accessing the lookup table to determine a remapped address for the received address when the received address matches an address that is associated with the one or more defective memory cells. Based on a determination that the received address matches an address associated with one or more defective memory cells in the memory array, the method passes to block 706 where the redundant storage on the additional die (e.g., redundant storage 516 and/or 612 of FIGS. 5-6) is accessed based on a remapped address associated with the received address.

Returning to block 704, based on a determination that the received address does not match an address associated with one or more defective memory cells in the memory array at the additional die, the method continues at block 708 where the redundant circuitry (e.g., redundant memory circuitry 512 of FIG. 5) on each memory die determines whether the received address matches an address associated with one or more defective memory cells in the memory array. The method may include determining, at each memory die, if the received address matches one or more addresses that are stored at that memory die and that are associated with one or more defective memory cells in the memory array on that memory die. The method can include accessing a fuse array (e.g., 412 in FIG. 4) or redundant memory circuitry (e.g., 512 in FIG. 5) at each memory die to determine whether the received address matches one or more addresses that are associated with one or more defective memory cells. The method may include determining, at one or more memory dies, a remapped address for the received address when the received address matches an address that is associated with one or more defective memory cells. For example, remapped addresses can be stored in fuse registers, such as the fuse registers 418 of FIG. 4.

Based on a determination that the received address matches an address that is stored on at least one memory die and that is associated with one or more defective memory cells in the memory array on the at least one memory die, the method passes to block 710 where the redundant memory (e.g., redundant memory 510 of FIG. 5) on the at least one memory die is access based on a remapped address that is associated with the received address. Based on a determination at block 708 that the received address does not match an address that is stored on at least one memory die, and that is associated with one or more defective memory cells in the memory array on the at least one memory die, the method continues at block 712 where the memory array on at least one memory die is access based on the received address.

In other embodiments, the method 700 may be performed by an additional die when the one or more memory dies do not include redundant memory. In such embodiments, blocks 708 and 710 are omitted and either the redundant storage on the additional die is accessed when a received address is associated with one or more defective memory cells in a memory array, or the memory array on at least one memory die is accessed when the received address is not associated with one or more defective memory cells in a memory array.

Although the flowchart depicts the block 704 and the block 708 as occurring sequentially, other embodiments are not limited to this implementation. The block 704 and the block 708 can be performed in parallel in certain embodiments.

The systems, methods, and apparatuses disclosed herein may allow for memory packages with additional die to replace or supplement redundant memory storage of memory die. This may increase the availability of redundant storage, which may improve package yields and/or reduce the amount of array space dedicated to redundant storage on memory die. This may reduce the array size and/or increase the space available for storing data.

The foregoing description, for purposes of explanation, uses specific nomenclature to provide a thorough understanding of the described embodiments. However, it will be apparent to one skilled in the art that the specific details are not required to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. An apparatus, comprising:
a memory device comprising a memory array; and
an additional die in communication with the memory device, the additional die comprising:
a redundancy check circuit configured to determine if an address for the memory array is associated with one or more defective memory cells in the memory array; and
redundant storage configured to store data associated with one or more defective memory cells in the memory array.

2. The apparatus of claim 1, wherein the redundancy check circuit is configured to output a match signal based on the address being associated with one or more defective memory cells in the memory array.

3. The apparatus of claim 2, wherein the additional die further comprises an address decoder configured to decode the address to access the redundant storage based on the match signal.

4. The apparatus of claim 1, wherein the redundancy check circuit comprises:
at least one storage configured to store one or more addresses associated with defective memory cells and a remapped address for each of the one or more addresses; and
a comparator circuit configured to compare the address with the one or more addresses associated with defective memory cells stored in the at least one storage.

5. The apparatus of claim 4, wherein the additional die further comprises:
a first selector circuit in communication with the redundant storage and the memory device, the first selector circuit configured to receive data read from the memory array or the redundant storage; and
a second selector circuit in communication with the redundant storage and the memory device, the second selector circuit configured to receive data to be written to the memory array or the redundant storage.

6. The apparatus of claim 1, wherein the memory device and the additional die are included in a memory package.

7. The apparatus of claim 1, wherein the memory device and the additional die are included in a memory module.

8. The apparatus of claim 1, wherein the memory device comprises:
redundant memory configured to store data associated with one or more defective memory cells in the memory array; and
redundant memory circuitry configured to store remapped addresses for the redundant memory.

9. A memory package, comprising:
a plurality of memory devices, each memory device in the plurality of memory devices comprising a memory array; and
an additional die in communication with the plurality of memory devices, the additional die comprising:
a redundancy check circuit configured to determine if a received address for the memory array on at least one memory device of the plurality of memory devices is a defective memory address; and
redundant storage configured to store data associated with one or more defective addresses for the memory array.

10. The memory package of claim 9, wherein the redundancy check circuit is configured to output a match signal when the received address is a defective address.

11. The memory package of claim 10, wherein the additional die further comprises an address decoder configured to decode the received address to enable the redundant storage to be accessed based on the match signal.

12. The memory package of claim 9, wherein the redundancy check circuit comprises:
at least one storage configured to store one or more defective addresses and a remapped address for each of the one or more defective addresses; and
a comparator circuit configured to compare the received address with the one or more defective addresses stored in the at least one storage.

13. The memory package of claim 12, wherein the additional die further comprises:
a first selector circuit in communication with the redundant storage and the plurality of memory devices, the first selector circuit configured to receive data from the plurality of memory devices or the redundant storage; and
a second selector circuit in communication with the redundant storage and the plurality of memory devices, the second selector circuit configured to provide data to the plurality of memory devices or the redundant storage.

14. The memory package of claim 9, wherein each memory device of the plurality of memory devices comprises:
redundant memory configured to store data associated with one or more defective memory cells in the memory array; and
redundant memory circuitry configured to access the redundant memory.

15. A method, comprising:
receiving, by an additional die and a memory device, an address for a memory array on the memory device;
accessing redundant storage on the additional die based on the address being associated with one or more defective memory cells in the memory array; and
accessing the memory array on the memory device based on the address not being associated with one or more defective memory cells in the memory array.

16. The method of claim 15, wherein:
the redundant storage on the additional die is accessed when data associated with the address is stored in the redundant storage; and
the method further comprises:
accessing redundant memory on the memory device based on the address being associated with one or more defective memory cells in the memory array.

17. The method of claim 16, wherein accessing the redundant memory on the memory device based on the address being associated with the one or more defective memory cells in the memory array comprises determining, at the memory device, if the address matches one or more addresses stored at the memory device that are associated with the one or more defective memory cells, wherein the redundant memory on the memory device is accessed when the address matches an address associated with the one or more defective memory cells.

18. The method of claim 15, wherein accessing the redundant storage on the additional die based on the address being associated with the one or more defective memory cells in the memory array comprises comparing, at the additional die, the address to one or more addresses stored at the additional die that are associated with the one or more defective memory cells, wherein the redundant storage on the additional die is accessed when the address matches an address associated with the one or more defective memory cells.

19. The method of claim 15, wherein accessing the memory array on the memory device based on the address not being associated with the one or more defective memory cells in the memory array comprises determining, at the memory device, if the address matches one or more addresses stored on the memory device that are associated with the one or more defective memory cells, wherein the memory array on the memory device is accessed when the address does not match one or more addresses associated with the one or more defective memory cells.

20. The method of claim 15, wherein the address for the memory array is received from a controller.
